(19) United States
(12) Patent Application Publication
(10) Pub. No.: US 2009/0107401 A1
(43) Pub. Date: Apr. 30, 2009

(54) DEVICE FOR VAPORIZING CONDENSED SUBSTANCES

(76) Inventors: Markus Reinhold, Hilden (DE); Gerhard Karl Strauch, Aachen (DE); Markus Gersdorff, Aachen (DE); Nico Meyer, Aachen (DE); Florenz Kittle, Herzogenrath (DE)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/722,700

(22) PCT Filed: Dec. 16, 2005
(86) PCT No.: PCT/EP2005/056841

§ 371 Date: Apr. 15, 2008

(30) Foreign Application Priority Data
Dec. 24, 2004 (DE) 102004062552.2

(51) Int. Cl. C23C 16/448

(52) U.S. Cl. 118/726

(57) ABSTRACT

The invention relates to a device for the vaporisation of condensed (solid or liquid) materials, in particular, of starting materials for OLED production, comprising a container (1), for housing the material with a gas supply line (2) and a gas exhaust line (3). A number of inserts (4) for housing the material are arranged in the container (1) which have an individual flow thereover, whereby the inserts (4) are arranged one over the other in the vertical direction and comprise recesses (5) for housing the material in the horizontal direction over which a flow is possible. Several gas flows may flow in parallel over several inserts.

### RELATED APPLICATIONS

This is a U.S. National Stage of and claims priority to PCT/EP2005/056841, filed 16 Dec. 2005, which claims priority to DE 10200406552.2, filed 24 Dec. 2004.

### FIELD OF THE INVENTION

The present invention relates to a device for vaporizing condensed substances.

### BACKGROUND

In the OLED production by the OVPD method, sparingly volatile organic materials are vaporized in a source container, introduced into the deposition chamber, where they are condensed on a glass substrate. In contrast with the VTE source container, the transport of substance from the material source to the substrate does not take place by thermal activation in a vacuum but instead in the supply lines by means of a convective carrier gas stream at pressures in the Pascal range.

In recent years, this innovative technology has been developed further to technical production readiness. Until then, there was no method of effectively and controllably vaporizing sparingly volatile crystalline or amorphous organic materials, their melts or liquid organic materials.

To accelerate the phase transfer of the organic material in the source container, work is performed at elevated temperatures, e.g., in the range of 100° C. to 650° C. Typically, organic materials are unstable at these temperatures and decompose through oxidation processes and reaction with the surfaces of the material with which the organic substances come in contact. In the MOCVD process, the bubblers usually have a temperature lower than 50° C. Vaporization is therefore preferably accomplished by means of the inert gas nitrogen.

Vaporization that is stable over time and is reproducible from run to run is an obligatory prerequisite for OLED production. In the state of the art, there is no container design for the OLED process that is capable of achieving the required prerequisites for stability and reproducibility.

In addition, the source should supply reproducible results even at different operating pressures and temperatures. Finally, it is desirable if the source can be resupplied easily with consumable material.

### SUMMARY OF THE INVENTION

The object of the present invention is to improve upon a device for vaporizing condensed substances, in particular starting materials for OLED production, having a container (1) to hold the substance, having a gas inlet line (2) and a gas outlet line (3) in an advantageous utilitarian manner.

This object is achieved by the invention characterized in the claims, whereby not only claim 1 but also all the claims that are formally formulated as subclaims constitute independent approaches to solving this problem, and all the claims may be combined with one another in any form.

Claim 1 proposes first and essentially a plurality of inserts over which the flow can pass individually in the container. In a further embodiment of the invention, these inserts are arranged one above the other in the vertical direction. The inserts may have cup-shaped recesses in which the substance to be vaporized can be placed. Then the flow preferably passes over the substance in the horizontal direction. Gas flow baffles are provided in the container to deflect the oncoming flow, so that the flow passes over the recesses in the individual inserts and vaporized starting material can accumulate in the carrier gas stream. There are essentially two possibilities by which the flow can be passed over the individual inserts. In the first alternative, the oncoming flow is divided into multiple flows over the recesses of the inserts in parallel with one another. These multiple flows over the recesses then flow in a common outgoing flow through the gas outlet. In a second alternative, an individual gas flow is passed over all the recesses of the inserts one after another. The parallel connection mentioned first as well as the alternative serial connection are preferred. It is also possible to combine the two connections, so that the carrier gas flows in

parallel over multiple inserts. In a special embodiment of the invention, the gas flow baffles are formed by the inserts themselves. These serve in particular to deflect an oncoming flow, in particular a vertical flow, into one or more flows passing across it and for deflecting the flow(s) into an outgoing flow running across it. The incoming flow and outgoing flow thus run essentially parallel to one another. The inserts may be arranged one above the other in such a way that the bottom of one insert covers a cup-shaped recess in the insert below it. These are arranged at such a distance that an overflow channel is formed. The inserts may be situated in a tubular container in such a way that a passage and/or the container wall and an edge recess in each insert form a flow channel. This may be the oncoming flow or the outgoing flow channel. Furthermore, the inserts preferably have two diametrically opposed shaft-like recesses in the wall. The gas flow can enter and leave through these recesses in the wall, each forming a step. The inserts may sit on their elevated edge sections so that they are easy to assemble. Furthermore, the inserts may sit on a spacer, which is supported with respect to the bottom of the container. By means of spacers of different heights, the number of inserts accommodated in the container can be varied. In addition, it is also possible to provide for another spacer to be situated between the insert stack and the cover of the container, and this spacer may also be replaced. The container may be made of metal. The preferred metal here is aluminum. The insert may also be made of the same material. In a preferred embodiment, the recess and the insert is lined with a suitable material; for example, a cup that holds the substance to be vaporized may be accommodated in the recess. The cup may be made of a ceramic material or quartz or a suitable metal. Inorganic compounds are especially preferred. Graphite is also a suitable material.

The container is constructed in such a way that an optimal temperature homogeneity prevails therein. It may be made of aluminum. Its outer shell may be made of stainless steel to stabilize it mechanically. Other thermally stable materials are also possible. The shells also have an optimal temperature homogeneity. Each shell has essentially the same temperature in the radial direction. This is a result of the good thermal conductivity of the aluminum of which the shells are made. The axial temperature distribution over all shells is likewise ideally homogeneous because the aluminum shells are pressed against one another by the container cover with very good heat transfer. In addition, the shells are surrounded by an aluminum cylinder that acts as a homogenizer to homogenize any cold comers in the outer housing of the source container in the circumferential direction and in height and thus to provide shielding from the interior of the container

Reaction of the organic material with all surfaces with which it is in contact or may come in contact is prevented by using pure quartz glass. Secondary reaction of the gas with the surrounding container surfaces is suppressed by using pure or silicon-doped aluminum. The container is scalable in size without any effect on the function principle or the properties described above.

### BRIEF DESCRIPTION OF THE DRAWINGS

Exemplary embodiments of the present invention are explained below on the basis of the accompanying drawings, in which:

FIG. 1 shows a first exemplary embodiment in a side view,

FIG. 2 shows the first exemplary embodiment in a perspective view and a sectional view,

FIG. 3 shows a section along line II-II in FIG. 1,

FIG. 4 shows a section along line IV-IV in FIG. 3,

FIG. 5 shows a section along line V-V in FIG. 3,

FIG. 6 shows a section according to FIG. 4 with a second exemplary embodiment,

FIG. 7 shows a section according to FIG. 3 of the second exemplary embodiment,

FIG. 8 shows the use of a second exemplary embodiment in a perspective view,

FIG. 9 shows a diagram according to FIG. 2 of the second exemplary embodiment and

FIG. 10 shows a diagram according to FIG. 4 of a third exemplary embodiment.

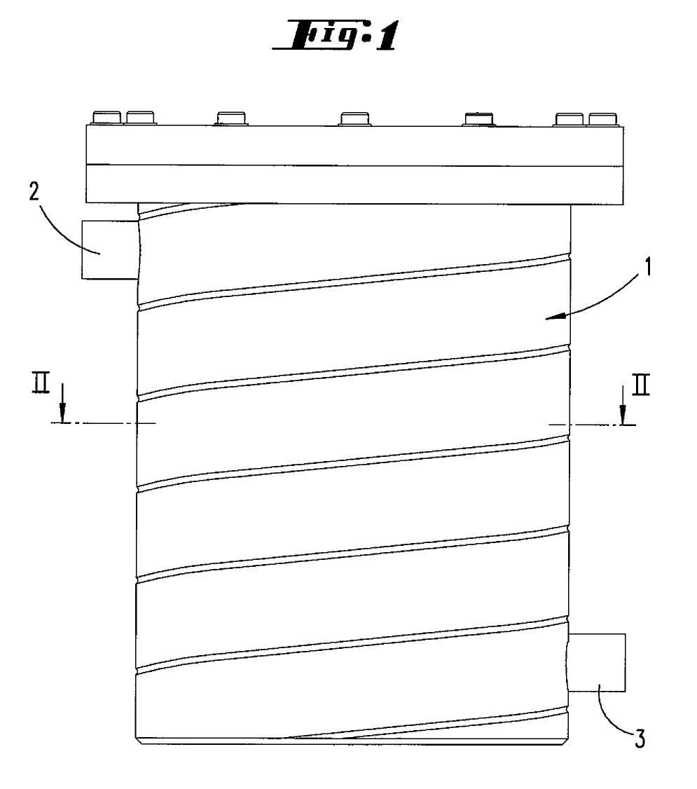

### DETAILED DESCRIPTION

The exemplary embodiments illustrated in the drawings have a container 1, which has an essentially circular cylindrical cross section and a tubular outer container wall. The container is tightly sealed with a cover 18. Just below the cover 18, the container 1 has a gas inlet line 2 and just above its bottom it has a gas outlet line 3.

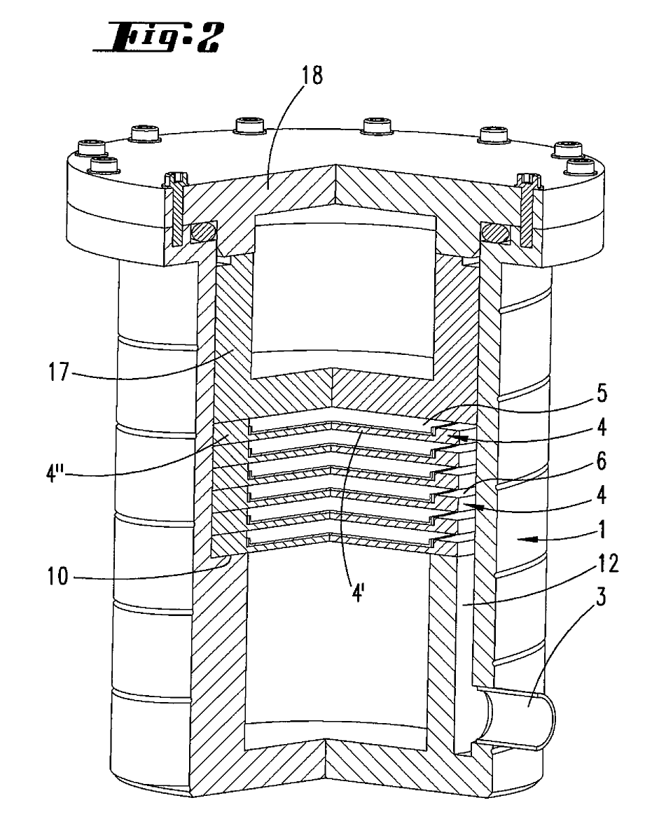

In the exemplary embodiment shown in FIG. 2, the container has a step 20 on which sits a stack of several inserts 4. The step may also be formed by a spacer 16, as illustrated in FIG. 9, where the spacer 16 is shown as being made of solid material. The spacer 17 shown in FIG. 2, which is situated between the stack of inserts 4 and the cover 8, is hollow. The lower spacer 16 may also be hollow.

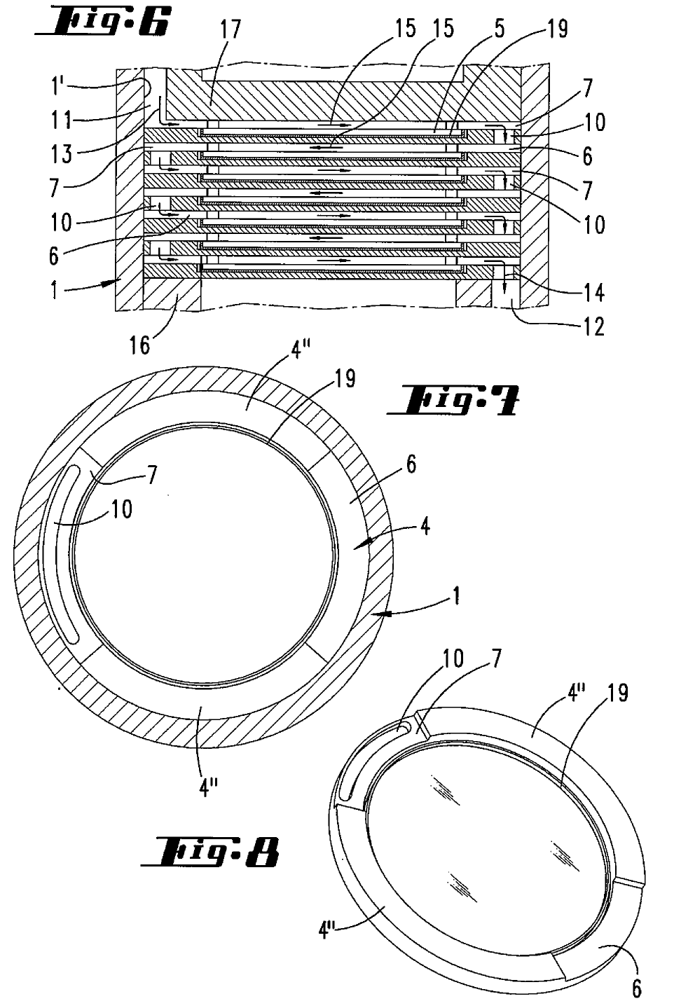

As indicated in FIGS. 4 and 6, the spacers 16 and 17 together with the inside wall 1′ of the container wall form a flow channel 11, 12. The incoming flow 13 flows through a flow channel 11. The outgoing flow 14 flows to the flow channel 12 running parallel to the former.

In a first exemplary embodiment, multiple inserts 4 are aligned in the same direction one above the other, so that the incoming flow 13 is divided into a plurality of flows 15 flowing across the incoming flow 13 and between the individual inserts 4. The flows 15 are combined on the diametrically opposite side to form a common outgoing flow 14, which flows through the flow channel 12 to the gas outlet line 3.

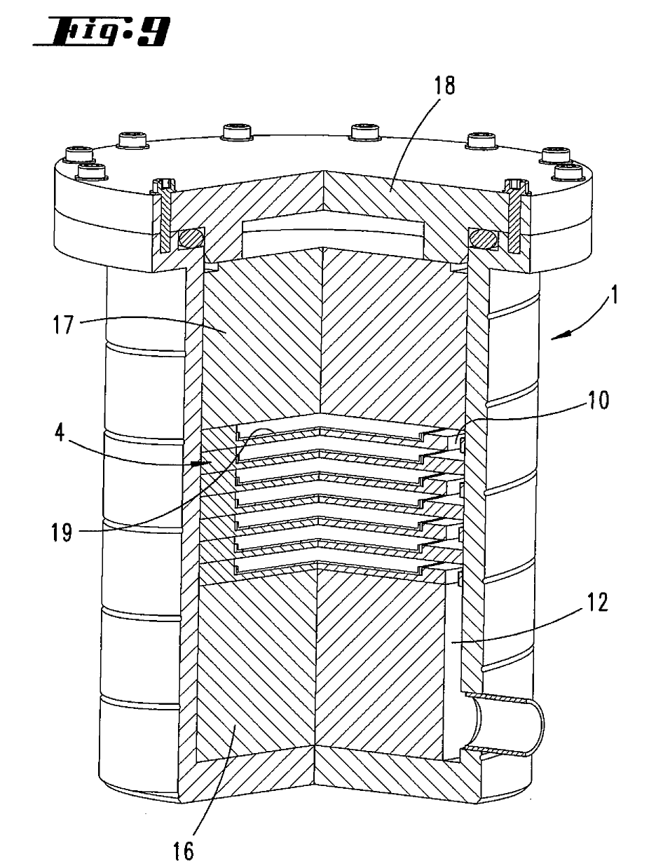

In the second exemplary embodiment (FIGS. 6 through 9) the incoming flow 13 is deflected completely to flow first as a flow 15 over a recess 5 in the top insert 4. It is then deflected and flows in the opposite direction over a recess 5 in an insert 4 situated beneath it as flow 15 in the opposite direction. In this exemplary embodiment, the incoming flow 13 flows over all recesses 5 of all inserts 4 without being divided and then leaves the container 1 as outgoing flow 14 through the gas outlet line 3.

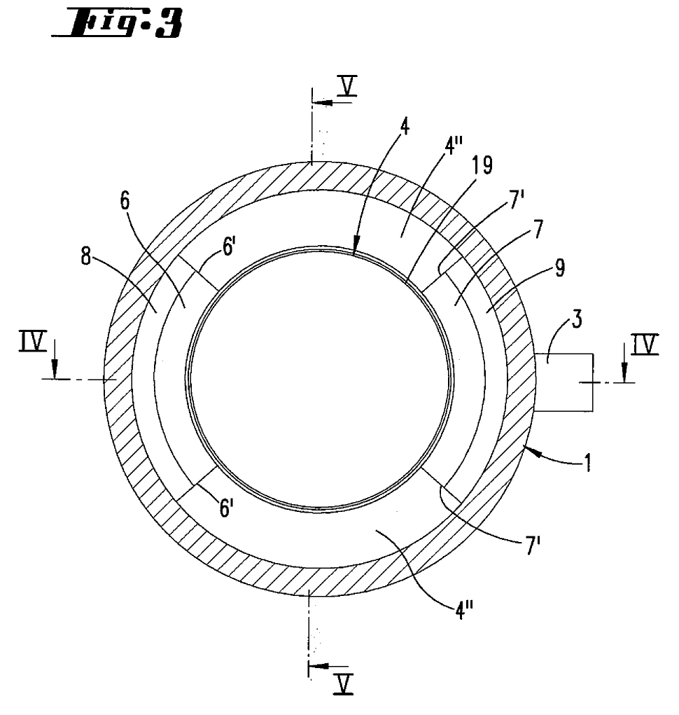

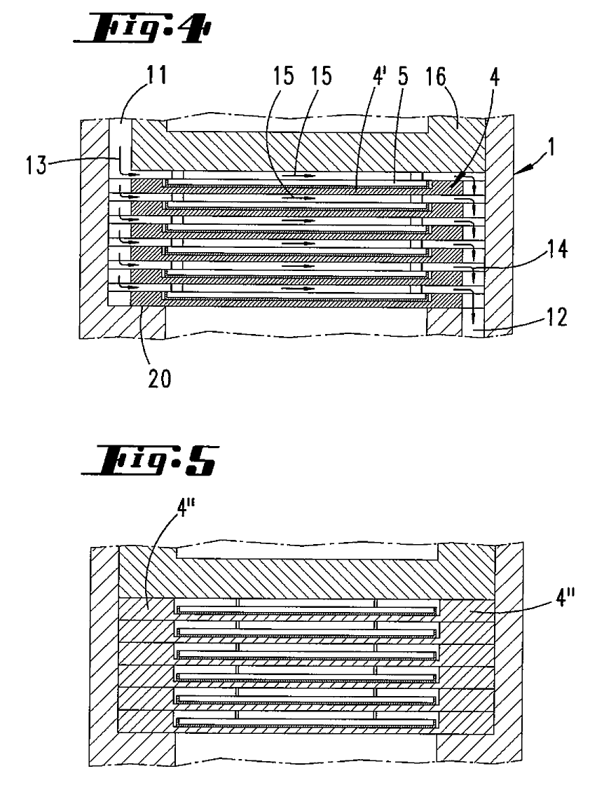

The two exemplary embodiments (FIGS. 2 through 5 and/or FIGS. 6 through 9) differ essentially in the shape of the inserts 4. The inserts shown in the FIGS. 2 through 5 each have edge recesses 8, 9 which together with the inside wall 1′ of the container wall form flow channels. In the area of these edge recesses 8, 9, which are diametrically opposed and correspond approximately to a quarter of a circle, the edge wall of the insert 4 is reduced in some areas. These steps together with the bottom of the insert 4 above them form an incoming flow channel 6 and an outgoing flow channel 7. Between the incoming flow channel 6 and the outgoing flow channel 7, there are higher wall sections 4″ on which the insert 4 situated above them sits. Thus, the bottom 4″ of an upper insert forms the cover for an overflow channel for the flow 15 flowing over a central recess 5 in the insert 4.

In the circular central recess 5, there is a cup 19, which may be made of a suitable material, e.g., quartz. The cup 19 serves to hold the substance to be vaporized.

In the exemplary embodiments, the boundary edges of the incoming flow channel 6 and the outgoing flow channel 7 are depicted as radial lines. This is just a schematic diagram. The side walls of the incoming flow channel 6 as well as the outgoing flow channel 7 are designed so that the flow 15 thereover passes uniformly over the recess 5. To this end, the walls 6′ and/or 7′ may have a suitable curved shape.

In the exemplary embodiment depicted in FIGS. 6 through 9, the inserts 4 also have diametrically opposed recessed edge sections 6, 7. However, this embodiment lacks edge recesses 8, 9 on both sides. Here there is merely an opening 10 to the insert 4 beneath. This opening may also be designed as an edge recess, but it is shaped there in the form of a curved elongated hole 10 through which the flow 15 leaves the insert 4 to flow over the recess 5 in the insert 4 underneath.

In a similar manner, the channels 8, 9 in the first exemplary embodiment may be formed by enclosed openings.

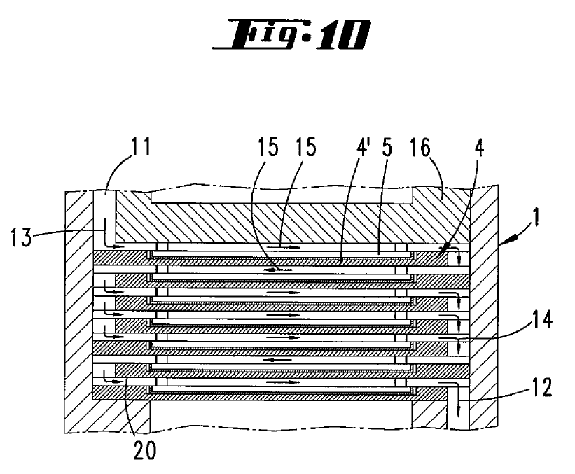

In the exemplary embodiment shown in FIG. 10, cups of different types are arranged one above the other so the flow passes over them here in parallel and serially simultaneously. First, the flow passes over the top cup. The gas flow is deflected downward. Then the flow passes over the second cup. The gas flow, which is then deflected downward, is split into three individual gas flows so that the flow passes over the third, fourth and fifth cups simultaneously from above. The outgoing flow from these three cups is then directed together over the sixth cup and back over the seventh cup. Through a combination of the various cups with one another, additional different flow paths can be created.

All the features disclosed here are essential to the invention (by themselves). Thus, the full disclosure content of the respective/attached priority documents (copy of the previous application) is herewith also included in the disclosure of the present patent application, also for the purpose of including features of these documents in claims in the present patent application.

What is claimed is:

1. A device for vaporizing condensed (solid or liquid) starting materials for OLED production, comprising: a container (1) to hold the starting materials, said container having a gas inlet line (2) and gas outlet line (3), and being characterized by a plurality of inserts (4) arranged in the container (1) to allow a carrier gas flow to pass over the inserts individually.

2. Device according to claim 1, characterized in that the inserts (4) are arranged one above the other in a vertical direction.

3. Device according to claim 1, characterized in that the inserts (4) have recesses (5) to hold the starting materials, the recesses arranged in the inserts such that the flow passes over the recesses in the horizontal direction.

4. Device according to claim 1, characterized in that multiple gas flows pass over a plurality of the inserts in parallel.

5. Device according to claim 1, wherein the inserts (4) are plate-like and have a cup-shaped recess (5) to hold the starting materials.

6. Device according to claim 1, characterized by gas-flow baffles (6-10) formed by the inserts (4) to deflect the carrier gas flow across the baffles and to deflect the flow into an outgoing flow.

7. Device according to claim 1, wherein the inserts (4) are arranged interchangeably one above the other.

8. Device according to claim 5, wherein the recesses (5) in the inserts (4) have flow passing over them in a parallel direction.

9. Device according to claim 5, wherein the recesses (5) in neighboring ones of the inserts (4) have flow passing over them in the opposite direction.

10. Device according to claim 1, wherein the carrier gas flow is deflected into a plurality of flows (15), aligned in parallel, and the plurality of flows (15) are deflected into a single outgoing flow (14).

11. Device according to claim 5, wherein the carrier gas flow passes over the recesses (5) in all the inserts (4) one after the other.

12. Device according to claim 5, wherein the cup-shaped recess (5) in an insert (4) is covered by a bottom (4′) of the insert (4) situated above it, forming an overflow channel.

13. Device according to claim 1, wherein the container (10 is tubular and the inserts (4) are arranged in the container (1) in such a way that a wall of the container (1) and an edge recess (8, 9) of each insert (4) form a flow channel.

14. Device according to claim 13, characterized by diametrically opposed shaft-like wall recesses (6, 7) in the inserts (4).

15. Device according to claim 14, characterized by an outgoing flow opening (10) arranged in one of the wall recesses (6, 7).

16. Device according to claim 15, wherein the outgoing flow opening (10) is a an elongated hole extending in a vertical direction.

17. Device according to claim 1, wherein the inserts (4) rest on edge sections (4″) of the inserts.

18. Device according to claim 5, wherein the cup-shaped recesses (5) are arranged one above the other and pressed against one another.

19. Device according to claim 5, wherein the cup-shaped recesses (5) are in temperature equalizing contact with one another over large areas of contact.

20. Device according to claim 5, wherein the cup-shaped recesses are made of aluminum, and are pressed against one another by a cover of the container.

21. Device according to claim 1, wherein the container is made of aluminum and is surrounded by a stainless steel jacket.
